(19) United States
(12) Patent Application Publication
(10) Pub. No.: US 2001/0006234 A1
(43) Pub. Date: Jul. 5, 2001

(54) Semiconductor device and method of manufacturing the same

(76) Inventor: Kohji Kanamori, Tokyo (JP)

Correspondence Address: Scully, Scott, Murphy & Prresser, 400 Garden City Plaza, Garden City, NY, 11530, US

(21) Appl. No.: 09/793,217

(22) Filed: Feb. 26, 2001

Related U.S. Application Data
(62) Division of application No. 09/338,170, filed on Jun. 22, 1999.

(30) Foreign Application Priority Data
Jun. 23, 1998 (JP) 175467/1998

(51) Int. Cl. H01L 29/04

(52) U.S. Cl. 257/57

(57) ABSTRACT

There are provided a semiconductor device having uniform electric characteristics that is a high insulation voltage transistor in which a low concentration impurity diffusion layer is used for a source region and a drain region, and a method of manufacturing the semiconductor device.

A transistor is provided which includes said source region and said drain region both being a low concentration impurity diffusion layer provided on a semiconductor substrate, and a channel region engaged with a gate electrode put between the aforementioned source and drain regions.

There is formed a high concentration diffusion layer in a region in the source and drain regions, which has a length L over the entire width of the channel region and which is formed such that at least the edge opposing to an end edge of the gate electrode is prevented from making contact with the end edge of the gate electrode, and contacts are disposed on the high concentration diffusion layer.

### BACKGROUND OF THE INVENTION

1. Field of the Invention

The present invention relates to a semiconductor device and a method of manufacturing a semiconductor device, and more particularly to a semiconductor device and a method of manufacturing a semiconductor device, the semiconductor device being a high integration semiconductor circuit such as an LSI or a ultra LSI in which it has a high insulation characteristics and satisfactorily ensures flexibility for a design in wiring and layout, etc.

2. Description of the Related Art

There are conventionally disclosed many known techniques concerning a method of manufacturing a non-volatile semiconductor memory including a flash memory.

For example, in U.S. Pat. No. 5,095,344 there is disclosed that in a flash memory, high voltage of 20V is used for erasing.

There is further reported a NAND flash memory titled “A 2.3 μm MEMORY CELL STRUCTURE FOR 16 Mb NAND EEPROMs” by R. SHIROTA in IEDM, 1990,in which there is disclosed that a high insulation voltage of 18V is used during writing and 20V while erasing.

When a voltage of about 20V is used in a flash memory chip in such a manner, there is required a circuit to selectively apply that voltage to a memory cell. Accordingly, a transistor used for such a circuit is needed to have at least an insulation voltage beyond the applied voltage.

Recently, there is developed a flash memory which requires insulation voltage beyond the foregoing 20V, preferably beyond 25V.

For realizing such a transistor having the insulation voltage beyond 25V, however, diffusion layers of a source and a drain should be deeply formed to bring the junction insulation voltage beyond 20V.

Such junction insulation voltage beyond 20V is generally realized between a P well and an N well, which provides an example of a deep diffusion layer.

It is therefore possible to realize the high insulation transistor being purposed by making use of such a well structure as a source and drain.

However, such a method suffers from a difficulty that since impurity concentrations of the source and the drain are very low, resistance is made high.

More specifically, even if a low impurity concentration region is formed, resistance along that region is high to cause parasitic resistance depending upon a position where contact is taken, so that characteristics of a transistor are altered owing to a disposition position of the contact and wiring layout, etc..

For this, even though impurity doping into a contact region is separately performed to reduce contact resistance, resistance from the contact to the channel is not ignored.

Further, such a method suffers from a difficulty that the number of processes is increased.

When herein a low impurity concentration well region in prior art is used to form the contact, and the number of the contacts or the positions of the same are properly altered in one region as illustrated in FIGS. 5(A), 5(B), 5(C) to inspect a change in characteristics of the transistor.

It is thereupon clarified that severe variations are produced in characteristics of the transistor depending upon disposition conditions of the contact in the transistor as illustrated in FIG. 6.

More specifically, for making uniform the characteristics of a transistor, flexibility in design is severely limited as found in the aforementioned prior art example.

In contrast, Japanese Laid-Open Patent Application Nos. Hei04-305573 and Hei08-181223 disclose a method of forming a high insulation transistor.

Therein, a high impurity concentration layer is formed in a low impurity concentration layer to form a contact in the high impurity concentration layer.

However, the example does not disclose a technique to make uniform characteristics of a plurality of transistors and ensure flexibility in a disposition layout design for a plurality of transistors.

Japanese laid-Open Patent Application Nos. Hei03-225963, Hei04-294546, and Hei09-045873 disclose a technique wherein a drain region is formed in a low impurity concentration layer, and a high impurity concentration layer is formed only in a periphery of a contact.

The technique however fails to disclose a technique, as in the aforementioned techniques, to make uniform characteristics of a plurality of transistors in a high integration semiconductor device to the utmost and secure flexibility in a disposition layout design of a plurality of transistors.

### SUMMARY OF THE INVENTION

In view of the above, it is an object of the present invention to provide a semiconductor device and a method of manufacturing the same having uniform electrical characteritics in a high insulation transistor where a low concentration impurity diffusion layer is used for a source and drain.

According to a first aspect of the present invention, there is provided a semiconductor device comprising:

a source and drain region of a low concentration impurity diffusion layer provided on a semiconductor substrate;

a gate electrode put between the source and the drain;

a channel region engaged with the aforementioned gate;

a high concentration diffusion layer formed on a region which has a length over the entire channel width of the channel region and includes an edge that faces to at least an end edge of the aforementioned gate electrode and that is formed as to prevent making contact with the end edge of the aforementioned gate electrode.

According to a second aspect of the present invention, there is provided a method of manufacturing a semiconductor device comprising the steps of:

forming in a predetermined first conductivity semiconductor substrate at least two mutually separated well regions into which a second conductivity impurity is injected with low concentration;

employing the aforementioned well region as a source and drain region and further employing a semiconductor substrate part having the first conductivity as a channel region;

forming a proper gate electrode through an insulating film on a substrate surface of the semiconductor substrate part having the aforementioned first conductivity used as the aforementioned channel region;

forming a high concentration diffusion layer in a region which has a longitudinal length equal to a length of the channel region over the entire of the channel width of the aforementioned channel region provided corresponding to the aforementioned gate electrode in the well region used as the aforementioned source region and the aforementioned drain region and which has such a width that at least an edge corresponding to the end edge of the aforementioned gate electrode is prevented from making contact with the end edge of said gate electrode; and

disposing and forming one or a plurality of contacts in the high concentration diffusion layer.

In the foregoing, uniform transistor characteristics are realized without depending upon the number and positions of contacts in a high insulation voltage transistor that uses a low concentration impurity diffusion layer as a drain and a source.

More specifically, in the high insulation voltage transistor, a low concentration impurity diffusion layer for realizing high insulation is used for a source and a drain, and a low resistance high concentration impurity diffusion layer is formed over the entire channel width separated by a predetermined distance from a gate end, and thereafter a contact is provided on the high concentration impurity diffusion layer.

In all high insulation voltage transistors, the high concentration impurity diffusion layer is formed at a pre-determined distance from a gate end, so that resistance from the high concentration impurity diffusion layer to the gate end is made uniform.

Further, since the high concentration impurity diffusion layer has low resistance therein, even if the number of the contacts and positions of the same are different from each other, resistance from the contact to the gate end can be made uniform.

Accordingly, in all high insulation voltage transistors uniform transistor characteristics are ensured independent of the number of the contacts and positions thereof.

### BRIEF DESCRIPTION OF THE DRAWINGS

The above and other objects, advantages and features of the present invention will be more apparent from the following description taken in conjunction with the accompanying drawings, in which:

FIG. 1 is a plan view illustrating the construction of a semiconductor device according to the preferred embodiment of the present invention;

FIG. 2 is a sectional view illustrating the construction of the semiconductor device according to the preferred embodiment of the present invention;

FIG. 3 is a graphical representation illustrating characteristics of a transistor obtained by the semiconductor device according to the preferred embodiment of the present invention;

FIGS. 4 (A) to (D) are sectional views illustrating procedures of manufacturing a semiconductor device according to the preferred embodiment of the present invention;

FIGS. 5 (A) to (C) are plan views illustrating the construction of a prior art semiconductor device; and

FIG. 6 is a graphical representation illustrating a comparison of transistor characteristics in prior art semiconductor devices.

### DETAILED DESCRIPTION OF THE PREFERRED EMBODIMENTS

In the following section, the preferred embodiment of the present invention will be described in detail with reference to the accompanying drawings.

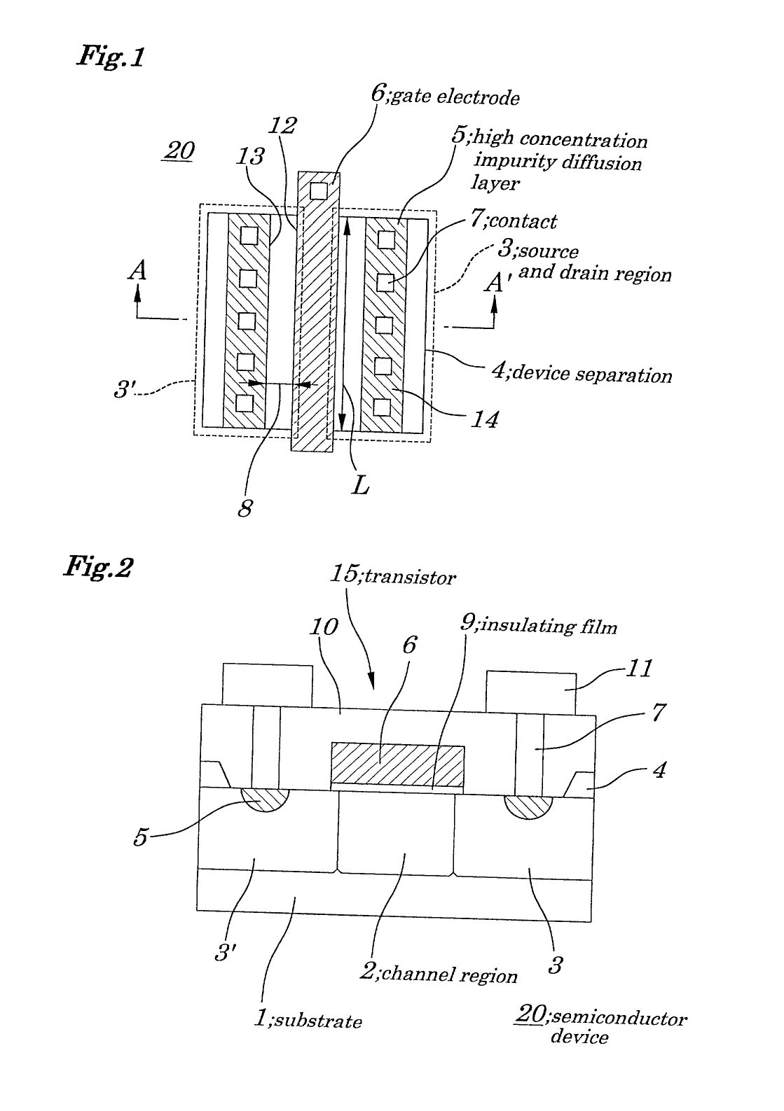

FIGS. 1 and 2 are a plan view and a sectional view each illustrating the arrangement of a preferred embodiment of a semiconductor device according to this embodiment, in which a transistor 15 is constructed with source and drain regions 3,3′ of a low concentration impurity diffusion layer provided on a semiconductor substrate 1, and a channel region 2 engaged with a gate electrode 6 put between the source and drain regions 3,3′, and a high concentration impurity diffusion layer 5, having an impurity concentration of at least above 10¹⁹ cm⁻³, is formed in an region 14 which is located in the source and drain regions 3,3′ such that at least an edge 13 facing to the end edge 12 of the gate electrode 6 is prevented from making contact with the end edge 12 of the gate electrode 6, and in which region has a length L over the entire channel width of the channel region 2, and a contact 7 is disposed in the high concentration impurity diffusion layer 5.

The semiconductor device 20 according to the present embodiment is preferably a high insulation semiconductor device, and insulation voltage of which semiconductor device 20 is preferably 20V.

The semiconductor device 20 is further desirably a high integration semiconductor device, and is also preferably a flash memory.

In contrast, in the semiconductor device 20 the end edge 12 of the gate electrode 6 and the edge 13 facing to the end edge 12 of the gate electrode 6 in the high concentration impurity diffusion layer 5 are needed to be formed, separated by a predetermined distance 8 from the end edge 12 of the gate electrode 6.

The high concentration impurity diffusion layer 5 is needed to be formed with a thickness which can not reach bottoms of the source and drain regions 3,3′.

In the present embodiment, one or a plurality of contacts 7 are formed on each high concentration impurity diffusion layer 5.

In the semiconductor device 20 according to the present embodiment, as described above, the high concentration impurity diffusion layer 5 is provided on the source and drain 3,3′ of the low concentration impurity diffusion layer over the entire of the channel width L, separated by the predetermined distance from the gate end 12, on which high concentration impurity diffusion layer 5 there is provided the contact 7 for each of the source and drain 3,3′.

The predetermined distance 8 from the gate end 12 is desirably a distance with which the high concentration impurity diffusion layer 5 can not reach the channel 2, and in all high insulation transistors 15 the high concentration impurity diffusion layer 5 is desirably formed through the predetermined distance 8.

Referring to FIG. 1, which is the plan view illustrating the high insulation transistor according to the present embodiment, there is formed over the entire of the channel width of the low resistance high concentration impurity diffusion layer 5, separated by the predetermined distance 8 from the gate end in accordance with the present embodiment in the arrangement wherein the low concentration impurity diffusion layer is used for the drain and source for realizing high voltage insulation.

In all high insulation transistors, resistance from the high concentration impurity diffusion layer 5 to the gate end can be made uniform by forming the high concentration impurity diffusion layer 5 at the predetermined distance from the gate end. Further, since the high concentration impurity diffusion layer has low resistance therein, resistance from the contact to the gate end can be made uniform in all high insulation transistors even though the number of the contacts and positions of the same are different from each other.

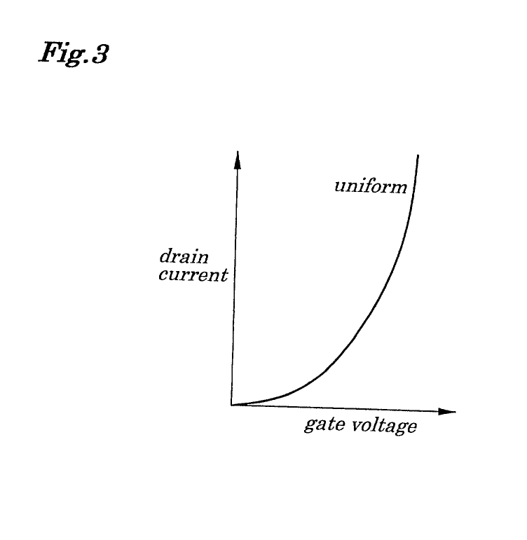

Accordingly, as illustrated in FIG. 3, uniform characteristics are ensured in all high insulation transistors independently from the number of contacts and positions of the same.

Referring to FIGS. 2 and 3, there will be described in detail a preferred embodiment of a method of manufacturing the semiconductor device 20 according to the present embodiment.

FIG. 2 is a sectional view illustrating a preferred embodiment of the method of manufacturing the semiconductor device according to the present embodiment.

More specifically, for realizing high insulation voltage of about 20V, preferably 25 to 30V there is needed a PN junction insulation voltage of at least 20V or more.

There is needed a low concentration impurity diffusion layer as a diffusion layer having such high insulation voltage.

Since in the present embodiment there is a supposed realization of a high insulation voltage transistor on a flash memory device that is one of non-volatile semiconductor memory devices, without causing increases of the number of manufacturing processes and the cost, a particular low concentration impurity diffusion layer is not formed unlike prior art, and a well known P well and N well are employed as the source and drain regions of the semiconductor device.

For this, as illustrated in FIG., 4(A), for forming a transistor 15 on a P substrate 1 for example a P type impurity is first doped as a formation region of a channel 2 to form a P well (2) being a low concentration diffusion layer, and in the next step for forming the source and drain regions 3,3′ an N type impurity is doped to form N wells (3,3′).

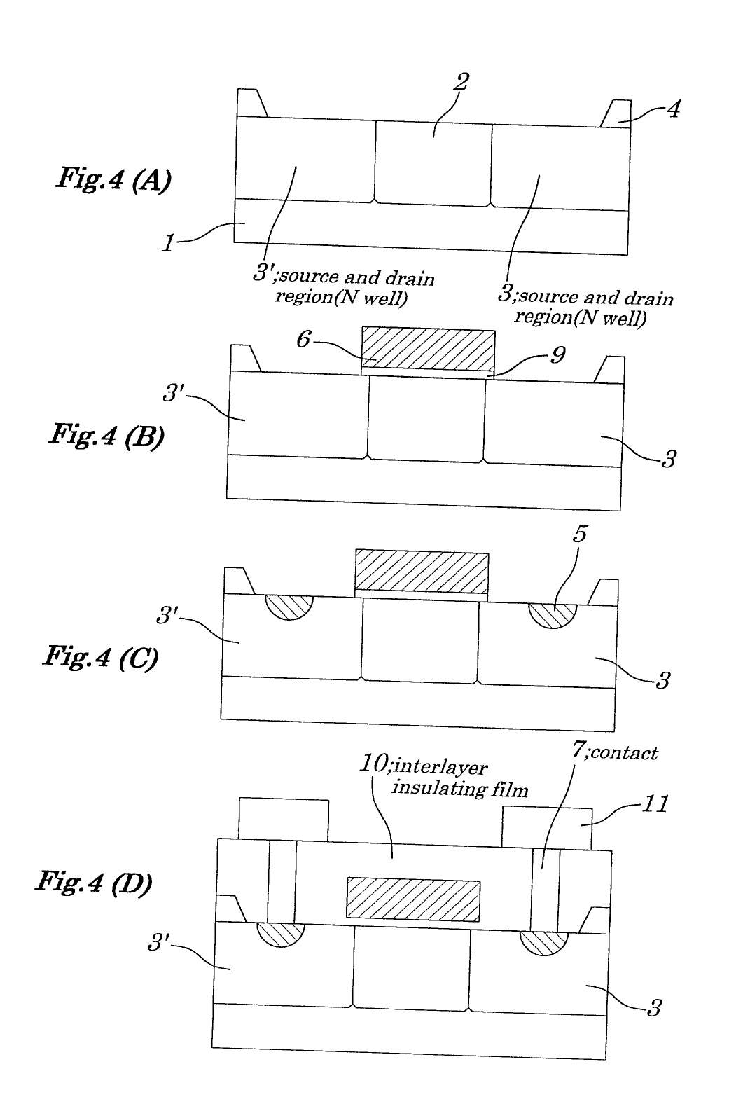

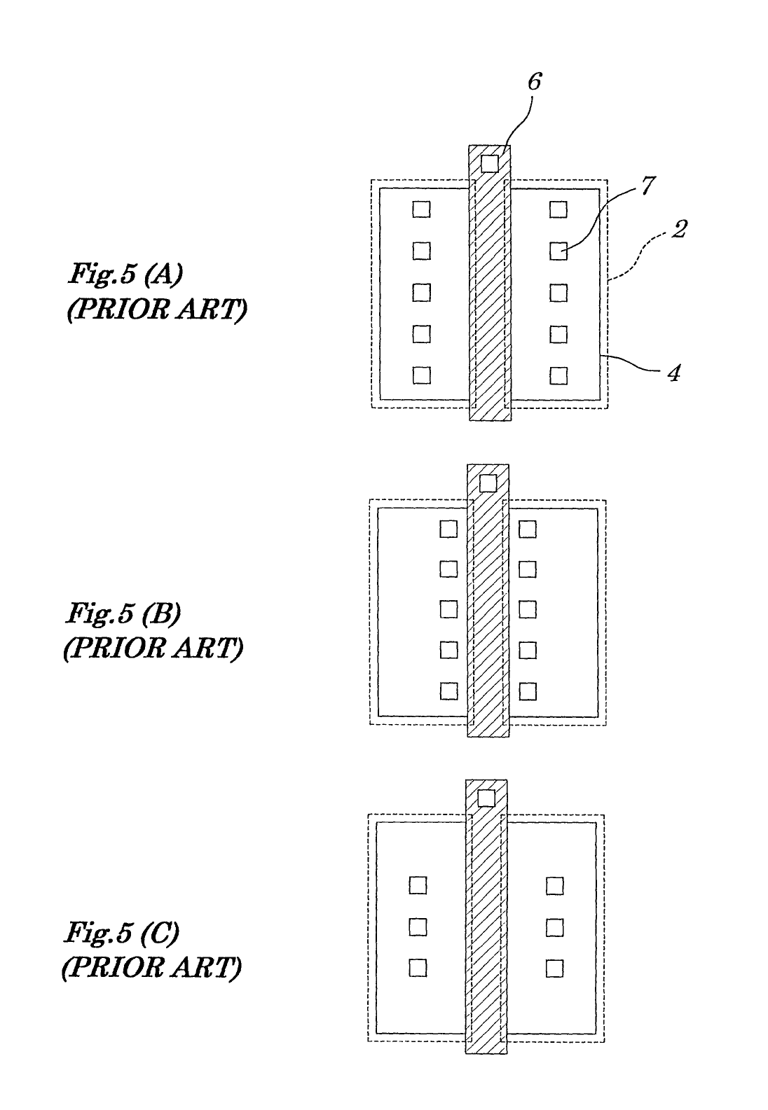

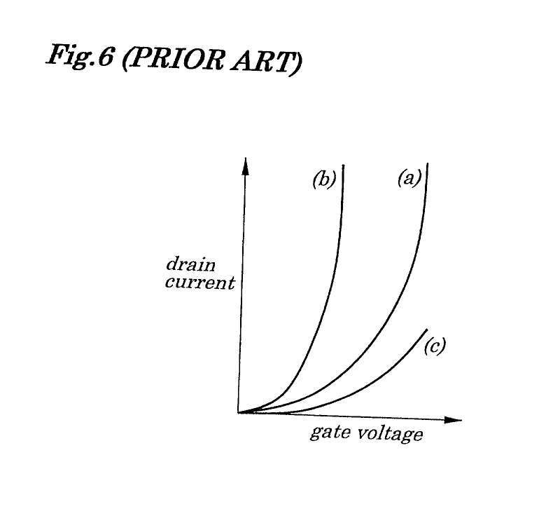

Then, as illustrated in FIG. 4(B), the gate electrode 6 is formed on an upper surface of the channel region 2 through a proper insulating film 9, and then as illustrated in FIG. 4(C), a N⁺high concentration diffusion layer 5 is provided in the low concentration source and drain 3,3′ in accordance with the present embodiment under conditions where the predetermined distance 8 is existent between the end 12 of the aforementioned gate 6 and the end 13 of the high concentration impurity diffusion layer 5 even when an N⁺diffusion layer being the high concentration impurity diffusion layer 5 diffuses from the end 12 of the gate 6.

Further, as illustrated in FIG. 4(D), the contact 7 for the source and drain regions 3,3′ is provided in the N⁺high concentration diffusion layer 5.

With such arrangement, in high insulation transistors having the same design parameter resistance from the contact to the gate 6 end can be made uniform irrespective of the number of the contacts and positions of the same.

Accordingly, as illustrated in FIG. 3, characteristics such as a current characteristic of a transistor can be made uniform.

Describing in more detail the aforementioned method of manufacturing a high insulation voltage transistor according to the present embodiment, as illustrated in FIG. 4(A), a P well (2) and an N well (3) are formed on the P type silicon substrate 1, and then device separation 4 is formed.

Then, as illustrated in FIG. 4(B), an insulating film (gate oxide film) 9 is formed by about 35 nm with a thermal oxidization process, and then polysilicon is deposited by about 300 nm, which is then patterned with a photolithography technique, and then the polysilicon is etched and removed to form the gate electrode 6.

Then, as illustrated in FIG. 4(C), the sample is patterned with photolithography such that the N⁺high concentration diffusion layer 5 is opened, and with a patterned resist used as a mask. An N type impurity for example is implanted with 70 keV energy with the dose of 5×10¹⁵ cm⁻² to activate the ion.

Thereafter, as illustrated in FIG. 4(D), an interlayer insulating film 10, being an oxide film, is deposited with a CVD process to form the contact 7 and a wiring 11.

In the aforementioned embodiment, the distance 8 from the gate 6 to the N⁺high concentration diffusion layer 5 is unified in all high insulation transistors, and for its value there is used a value beyond at least a diffusion layer length of the N⁺high concentration diffusion layer 5 or more.

The reason is because diffusion layer insulation is deteriorated when the N⁺high concentration diffusion layer reaches a boundary between the P well and the N well.

It is apparent that the present invention is not limited to the above embodiments but may be changed and modified without departing from the scope and spirit of the invention.

Finally, the present application claims the priority of Japanese Patent Application No. Hei10-175467 filed on Jun. 23, 1998, which is herein incorporated by reference.

What is claimed is:

1. A semiconductor device comprising:
a source region of a low concentration impurity diffusion layer provided on a semiconductor substrate;
a drain region of the low concentration impurity diffusion layer;
a gate region put between said source and said drain regions; and
a channel region engaged with said gate region;
a high concentration diffusion layer formed in an region which has its length over the whole channel width of said channel region and in which at least an edge part opposing to an end edge part of said gate electrode is prevented from making contact with the end edge of said gate electrode in said source region and said drain region; and
a contact disposed on said high concentration diffusion layer.

2. The semiconductor device according to claim 1 wherein said semiconductor device is a high insulation semiconductor device.

3. The semiconductor device according to claim 2 wherein insulation voltage of said high insulation voltage semiconductor device is 20V or higher.

4. The semiconductor device according to claim 1 wherein said semiconductor device is a high integration semiconductor device.

5. The semiconductor device according to claim 4 wherein said semiconductor device is a flash memory.

6. The semiconductor device according to any of claims 1 to 5 wherein the end edge of said gate electrode and an edge facing to the end edge of said gate electrode in said high concentration diffusion layer are formed, separated away by a predetermined distance from said end edge of said gate electrode.

7. The semiconductor device according to claim 1 wherein said high concentration diffusion layer has a thickness which does not reach bottoms of said source region and said drain region.

8. The semiconductor device according to claim 1 wherein a plurality of contacts are formed on each of the high concentration diffusion layers.

9. A method of manufacturing a semiconductor device comprising the steps of:
forming at least two mutually separated well regions into each of which a second conductivity impurity is doped at low concentration on a predetermined first conductivity semiconductor substrate;
employing said well region as a source and drain region, and further employing a semiconductor substrate part having first conductivity as a channel region;
forming a proper gate electrode on a substrate surface of the semiconductor part having the first conductivity employed as said channel region through an insulating film;
forming a high concentration diffusion layer in a region which has a longitudinal length equal to a length over the entire channel width of the channel region provided correspondingly to said gate electrode in the well region employed as said source and said drain regions and in which an end thereof opposing to at least the end edge of said gate electrode has width thereof formed such that the edge is prevented from making contact with the end edge of said gate electrode; and
disposing one or a plurality of contacts on said high concentration diffusion layer.

10. The method of manufacturing a semiconductor device according to claim 9 wherein insulation voltage in each transistor of said semiconductor device is set to be at least 20V or more, desirably 25V or more.

11. The method of manufacturing a semiconductor device according to claim 9 wherein said high concentration diffusion layer has an impurity concentration of at least above 10¹⁹ cm⁻³.
